(19) United States
(12) Patent Application Publication
(10) Pub. No.: US 2024/0334639 A1
(43) Pub. Date: Oct. 3, 2024

(54) APPARATUS AND SYSTEM FOR ADJUSTABLE, ROTATABLE PDU POSITIONING

(71) Applicant: Lenovo Enterprise Solutions (Singapore) Pte. Ltd., New Tech Park (SG)

(72) Inventors: J. Mark Weber, Wake Forest, NC (US); Colby Weingarten, Cary, NC (US); Mary Hailu, Raleigh, NC (US); Michael Reese Wing, Durham, NC (US)

(21) Appl. No.: 18/129,544

(22) Filed: Mar. 31, 2023

(51) Int. Cl. H05K 7/14; F16M 13/02

(52) U.S. Cl. CPC H05K 7/1492; F16M 13/02

(57) ABSTRACT

An apparatus and system for adjustable, rotatable positioning of a power distribution unit (“PDU”) relative to a rack. A planar bracket extends along a longitudinal axis and is configured to couple to a rack configured to house an electronic device. The planar bracket includes a slot extending parallel to the longitudinal axis. A mounting mechanism is configured to engage the planar bracket and includes a hinge element coupled to a support element. The hinge element includes a rod configured to move along the slot. The support element is configured to support a power distribution unit and to rotate relative to the rod.

### FIELD

The subject matter disclosed herein relates to power distribution management systems and more particularly relates to adjustable and rotatable power distribution assemblies.

### BACKGROUND

A power distribution unit (“PDU”) is an essential feature of server equipment racks. Typically, a PDU provides intelligent power management, increased load reliability, and dense cable organization. PDUs can be mounted anywhere within a rack enclosure as long as they have a long enough cord to reach a power source. Customers, however, tend to opt for vertically mounted PDUs, or “0 U PDUs”, that do not occupy any rack spaces due to their attachment to one of the rack's vertical rails.

Despite their popularity, currently available 0 U PDUs are often difficult to implement because of a lack of standardization between rack manufacturers with respect to mechanical interconnects. Additionally, vertically mounted PDUs tend to cause interference between the cabled PDU and racked electronic devices when service is needed.

### BRIEF SUMMARY

An apparatus and system for adjustable, rotatable positioning of a power distribution unit (“PDU”) relative to a rack are disclosed. In some embodiments, the apparatus includes a planar bracket and a mounting mechanism. The planar bracket extends along a longitudinal axis and is configured to couple to a rack configured to house one or more electronic devices. The planar bracket includes at least one slot extending parallel to the longitudinal axis. The mounting mechanism is configured to engage the planar bracket and includes a hinge element coupled to a support element. The hinge element includes a rod configured to engage the slot. The support element is coupled to the hinge element and configured to support a power distribution unit and to rotate relative to the rod.

According to another aspect of the invention, a system includes a rack, a planar bracket, a hinge element, and a support element. The rack is configured to retain at least one electronic device configured to couple to a power distribution unit having one or more ports. The planar bracket is coupled to the rack and extends along a longitudinal axis. In some embodiments, the planar bracket includes one or more slots extending therethrough. The hinge element includes a rod configured to engage the slot such that the rod is transverse to the longitudinal axis and is movable along the slot. The support element is coupled to the hinge element and is configured to support the power distribution unit adjacent to the rack. The support element is configured to rotate about an axis that is parallel to the longitudinal axis.

According to a third aspect of the invention, some embodiments of an apparatus include a planar bracket extending along a longitudinal axis. The planar bracket is configured to couple to a rack configured to house at least one electronic device. The planar bracket includes at least one slot extending parallel to the longitudinal axis and at least one channel extending in a direction transverse to the longitudinal axis and intersecting the slot.

A mounting mechanism is configured to engage the planar bracket. The mounting mechanism includes a hinge element, a fastener, a support element, and a securing element. The hinge element includes a rod configured to engage the slot such that the rod is movable along the slot. The hinge element also includes a post extending in a transverse direction relative to the rod. The post is configured to selectively engage the channel. The fastener is configured to fix a position of the rod relative to the slot.

The support element is coupled to the hinge element and configured to support a power distribution unit such that the power distribution unit is disposed parallel to the longitudinal axis. The support element is further configured to rotate relative to the rod. The securing element is configured to couple at least a portion of the power distribution unit to the support element.

The apparatus further includes at least one sensor coupled to the planar bracket and/or the mounting mechanism. The one or more sensors are configured to detect a position of the power distribution unit relative to the rack and to transmit a position signal to a processor that indicates the position.

### BRIEF DESCRIPTION OF THE DRAWINGS

A more particular description of the embodiments briefly described above will be rendered by reference to specific embodiments that are illustrated in the appended drawings. Understanding that these drawings depict only some embodiments and are not therefore to be considered to be limiting of scope, the embodiments will be described and explained with additional specificity and detail through the use of the accompanying drawings, in which:

FIG. 1 is a perspective view of a system including a rack and an adjustable, rotatable PDU according to various embodiments;

FIG. 2 is a perspective view of an apparatus providing adjustable, rotatable PDU positioning according to various embodiments;

FIG. 3 is a side view of an representative embodiment of an apparatus providing adjustable, rotatable PDU positioning in accordance with the disclosure;

FIG. 4 is a back view of the apparatus of FIG. 3;

FIG. 5 is a perspective view of a representative embodiment of a planar bracket according to the disclosure;

FIG. 6 is a perspective view of a representative embodiment of a support element according to the disclosure;

FIG. 7 is a perspective view of a representative embodiment of a hinge element in accordance with the disclosure;

FIG. 8 is a perspective view of another embodiment of a hinge element in accordance with the disclosure;

FIG. 9A is a perspective view of still another embodiment of a hinge element in accordance with the disclosure; and

FIG. 9B is a cross-sectional view of segment A-B of the hinge element of FIG. 9A.

### DETAILED DESCRIPTION

Reference throughout this specification to “one embodiment,” “an embodiment,” or similar language means that a particular feature, structure, or characteristic described in connection with the embodiment is included in at least one embodiment. Thus, appearances of the phrases “in one embodiment,” “in an embodiment,” and similar language throughout this specification may, but do not necessarily, all refer to the same embodiment, but mean “one or more but not all embodiments” unless expressly specified otherwise. The terms “including.” “comprising.” “having.” and variations thereof mean “including but not limited to,” unless expressly specified otherwise. An enumerated listing of items does not imply that any or all of the items are mutually exclusive, unless expressly specified otherwise. The terms “a,” “an,” and “the” also refer to “one or more” unless expressly specified otherwise.

Furthermore, the described features, structures, or characteristics of the embodiments may be combined in any suitable manner. One skilled in the relevant art will recognize, however, that embodiments may be practiced without one or more of the specific details, or with other methods, components, materials, and so forth. In other instances, well-known structures, materials, or operations are not shown or described in detail to avoid obscuring aspects of an embodiment.

Aspects of the embodiments are described below with reference to schematic flowchart diagrams and/or schematic block diagrams of methods, apparatuses, and systems, according to embodiments. Although various arrow types and line types may be employed in the flowchart and/or block diagrams, they are understood not to limit the scope of the corresponding embodiments. Indeed, some arrows or other connectors may be used to indicate only the logical flow of the depicted embodiment. For instance, an arrow may indicate a waiting or monitoring period of unspecified duration between enumerated steps of the depicted embodiment. It will also be noted that each block of the block diagrams and/or flowchart diagrams, and combinations of blocks in the block diagrams and/or flowchart diagrams, can be implemented by special purpose hardware-based systems that perform the specified functions or acts, or combinations of special purpose hardware and code.

The description of elements in each figure may refer to elements of proceeding figures. Like numbers refer to like elements in all figures, including alternate embodiments of like elements.

As used herein, a list with a conjunction of “and/or” includes any single item in the list or a combination of items in the list. For example, a list of A, B and/or C includes only A, only B, only C, a combination of A and B, a combination of B and C, a combination of A and C or a combination of A, B and C. As used herein, a list using the terminology “one or more of” includes any single item in the list or a combination of items in the list. For example, one or more of A, B and C includes only A, only B, only C, a combination of A and B, a combination of B and C, a combination of A and C or a combination of A, B and C. As used herein, a list using the terminology “one of” includes one and only one of any single item in the list. For example, “one of A, B and C” includes only A, only B or only C and excludes combinations of A, B and C.

As described above, vertically mounted PDUs, or “0 U PDUs”, are often preferred since they do not occupy any rack spaces as a result of their attachment to one of the rack's vertical rails. Despite their popularity, currently available 0 U PDUs are often difficult to implement because of a lack of standardization between rack manufacturers with respect to mechanical interconnects. Additionally, vertically mounted PDUs tend to cause interference between the cabled PDU and racked electronic devices when service is needed. The apparatuses and systems described herein address these and other issues.

An apparatus and system for adjustable, rotatable positioning of a power distribution unit (“PDU”) relative to a rack are disclosed. In some embodiments, the apparatus includes a planar bracket and a mounting mechanism. The planar bracket extends along a longitudinal axis and is configured to couple to a rack configured to house one or more electronic devices. The planar bracket includes at least one slot extending parallel to the longitudinal axis. The mounting mechanism is configured to engage the planar bracket and includes a hinge element coupled to a support element. The hinge element includes a rod configured to engage the slot. The support element is coupled to the hinge element and configured to support a power distribution unit and to rotate relative to the rod.

In some embodiments, the rod is movable along the slot to adjust a position of the mounting mechanism with respect to the planar bracket. In some embodiments, the planar bracket includes one or more channels extending in a direction transverse to the longitudinal axis. The one or more channels intersect the slot. In some embodiments, the rod includes a securing bar extending in a transverse direction relative thereto. In some embodiments, the securing bar is configured to selectively engage the channel. Some embodiments include one or more fasteners configured to fix a position of the mounting mechanism relative to the slot.

In some embodiments, the support element is configured to support the power distribution unit such that the power distribution unit is disposed parallel to the longitudinal axis. In some embodiments, the support element is configured to couple to an end of the power distribution unit. In some embodiments, the support element includes at least one securing element configured to couple at least a portion of the power distribution unit to the support element. In some embodiments, the securing element includes an aperture and/or a retaining bar configured to receive a strap therethrough.

In some embodiments, the rack includes one or more apertures and the planar bracket includes an attachment element configured to engage the aperture such that the planar bracket is coupled to the rack. In some embodiments, the apparatus includes one or more sensors coupled to the planar bracket and/or the mounting mechanism. The one or more sensors are configured to detect a position of the support element relative to the planar bracket.

According to another aspect of the invention, a system includes a rack, a planar bracket, a hinge element, and a support element. The rack is configured to retain at least one electronic device configured to couple to a power distribution unit having one or more ports. The planar bracket is coupled to the rack and extends along a longitudinal axis. In some embodiments, the planar bracket includes one or more slots extending therethrough. The hinge element includes a rod configured to engage the slot such that the rod is transverse to the longitudinal axis and is movable along the slot. The support element is coupled to the hinge element and is configured to support the power distribution unit adjacent to the rack. The support element is configured to rotate about an axis that is parallel to the longitudinal axis.

In some embodiments, the system further includes at least one sensor coupled to the planar bracket, the hinge element, the support element, and/or the rack. The one or more sensors are configured to detect a position of the power distribution unit relative to the rack. In some embodiments, the one or more sensors include a location sensor, a position sensor, an optical sensor, and/or a motion sensor. In some embodiments, the system further includes a processor in communication with the one or more sensors. The processor is configured to determine an orientation of the power distribution unit based on the position. In some embodiments, the process is further configured to recommend one or more service action steps to a user based on the orientation.

In some embodiments, the planar bracket further includes at least one channel intersecting the one or more slots in a direction transverse to the longitudinal axis. In some embodiments, the rod includes a securing bar extending in a transverse direction relative thereto and configured to selectively engage the channel. In some embodiments, the support element is configured to support the power distribution unit such that the power distribution unit is disposed parallel to the longitudinal axis.

According to a third aspect of the invention, some embodiments of an apparatus include a planar bracket extending along a longitudinal axis. The planar bracket is configured to couple to a rack configured to house at least one electronic device. The planar bracket includes at least one slot extending parallel to the longitudinal axis and at least one channel extending in a direction transverse to the longitudinal axis and intersecting the slot.

A mounting mechanism is configured to engage the planar bracket. The mounting mechanism includes a hinge element, a fastener, a support element, and a securing element. The hinge element includes a rod configured to engage the slot such that the rod is movable along the slot. The hinge element also includes a securing bar extending in a transverse direction relative to the rod. The securing bar is configured to selectively engage the channel. The fastener is configured to fix a position of the rod relative to the slot.

The support element is coupled to the hinge element and configured to support a power distribution unit such that the power distribution unit is disposed parallel to the longitudinal axis. The support element is further configured to rotate relative to the rod. The securing element is configured to couple at least a portion of the power distribution unit to the support element.

The apparatus further includes at least one sensor coupled to the planar bracket and/or the mounting mechanism. The one or more sensors are configured to detect a position of the support element relative to the planar bracket and to transmit a position signal to a processor that indicates the position.

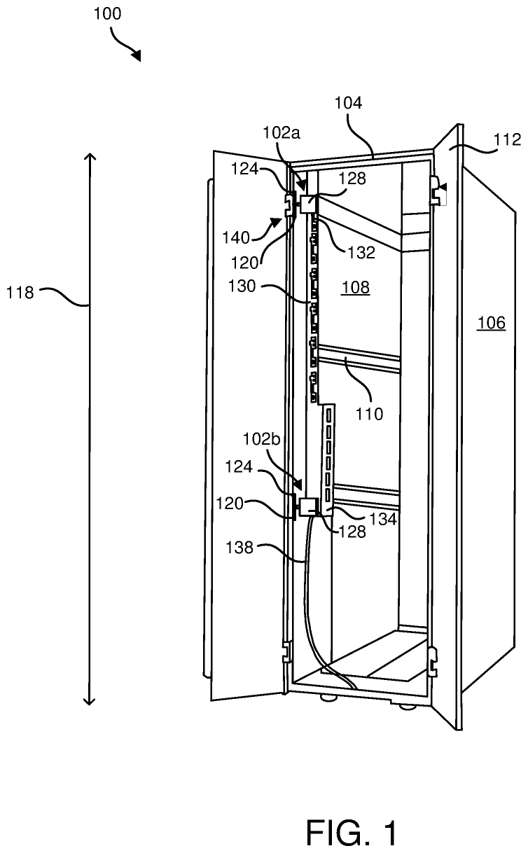

FIG. 1 illustrates an example environment in which embodiments of a system 100 and an apparatus 102 in accordance with the disclosure may operate. As shown, some embodiments of the system 100 for adjustable and rotatable PDU positioning may include a rack 104 configured to retain one or more electronic devices such as servers, network switches, routers, telecommunications hardware, and the like. Some embodiments of the rack 104 may include a structure such as an open frame, an enclosure, or a wall-mount. The rack 104 may include any material or combination of materials having sufficient strength and rigidity to support the weight of various electronic devices and to resist the heat produced by their operation. In some embodiments, for example, the rack 104 may include wood, plastic, commercial-grade steel, a composite material, or any other suitable material.

In some embodiments, the rack 104 may include a chassis 106 having one or more side panels 108. In some embodiments, the chassis 106 may further include one or more doors configured to selectively enclose and/or lock the electronic devices inside. In some embodiments, the side panels 108 and/or doors 112 may be ventilated to provide airflow through the enclosed chassis 106 and around any installed electronic devices or other equipment. In some embodiments, the side panels 108 may be removable.

In some embodiments, the chassis 106 may include one or more rails 110, shelves, trays, or other suitable support mechanism integrated with or coupled to the chassis 106 and/or side panels 108. In some embodiments, the rails 110 may be mounted vertically, horizontally, or in any other suitable manner. In some embodiments, the rails 110 may be made from 11-gauge steel formed into an L-shape. In certain embodiments, the rails 110 may include a plurality of mounting holes (not shown) having dimensions and spacing conforming to an applicable industry standard, such as Electronic Industries Alliance (EIA 310-D), and the Deutsches Institut für Normung (DIN 41494). The mounting holes (not shown) may be pre-threaded for machine screws, such as 10-32 machine screws. In other embodiments, sheet metal screws or any suitable fastening mechanism may be used in connection with the mounting holes (not shown).

In some embodiments, an apparatus 102 to provide adjustable and rotatable PDU positioning may be coupled to the rack 104 via a planar bracket 120. In some embodiments, the planar bracket 120 extends along a longitudinal axis 118 and includes an attachment element 124 configured to couple the planar bracket 120 to the rack 104. For example, in certain embodiments, the attachment element 124 may include a button, a projection, a clip, a screw, a rivet, or any other suitable element. In some embodiments, the attachment element 124 may be configured to engage a corresponding feature such as a mounting hole or other fastening mechanism coupled to or integrated into the rack 104. In one embodiment, the attachment element 124 may include a button configured to engage a key-hole mounting hole of the rack 104.

In some embodiments, a mounting mechanism 140 may be configured to engage the planar bracket 120 such that the power distribution unit 130 may be retained adjacent to the rack 104. In some embodiments, the mounting mechanism 140 may include a support element 128 to orient the power distribution unit 130 vertically relative to the rack 104. In this manner, the power distribution unit 130 may be retained parallel to the longitudinal axis 118 of the planar bracket 120. In these and other embodiments, the power distribution unit 130 may be a 0 U PDU with an attached power cord 138.

In certain embodiments, a first apparatus 102a may be configured to support one end of the power distribution unit 130 and a second apparatus 102b may be configured to support an opposite end of the power distribution unit 130. The planar bracket 120 of each apparatus 102 may be secured to a corresponding portion of the rack 104 such that the power distribution unit 130 is securely retained adjacent to the rack 104.

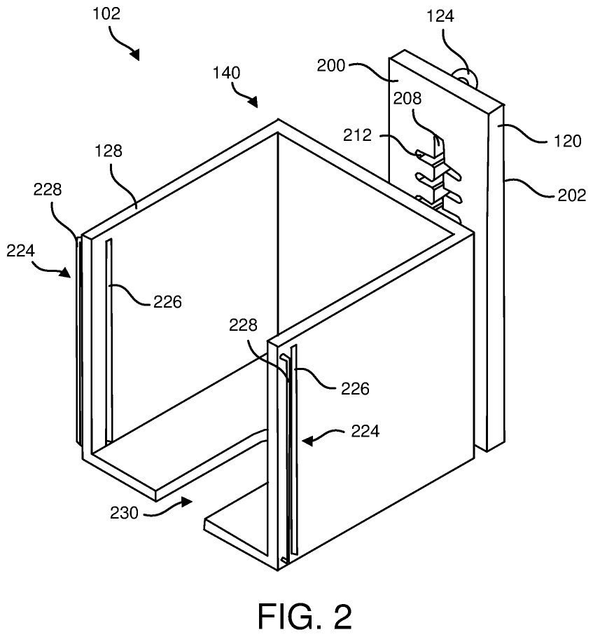

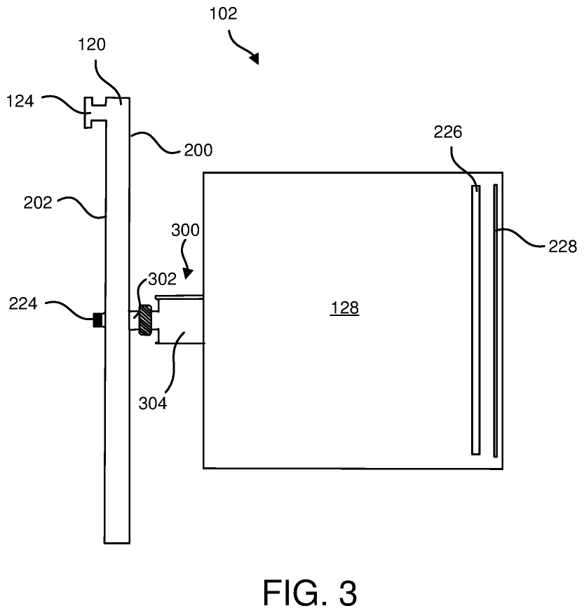

Referring now to FIGS. 2 and 3, in some embodiments, the planar bracket 120 may include a front surface 200 and a back surface 202. In some embodiments, one or more vertical slots 208 may extend through the planar bracket 120 from the front surface 200 to the back surface 202 in a direction parallel to the longitudinal axis 118. In one embodiment, a single vertical slot 208 may be centrally disposed in the planar bracket 120 and may include dimensions sufficient to accommodate at least a portion of the mounting mechanism 140. In this manner, a position of the mounting mechanism 140 relative to the planar bracket 120 may be adjusted by moving the mounting mechanism 140 along the slot 208.

In some embodiments, the mounting mechanism 140 may include a hinge element 300 coupled to the support element 128. The hinge element 300 may include a hinge 304 coupled to a rod 302. The hinge 304 may be configured to rotate the support element 128 relative to the rod 302. In some embodiments, the rod 302 may extend in a transverse direction relative to the hinge 304 and may be configured to engage the slot 208.

In some embodiments, the rod 302 may include a diameter or width smaller than a width of the slot 208. In these and other embodiments, the rod 302 may project through the slot 208 and extend through the back surface 202 of the planar bracket 120, while the hinge 304 and the support element 128 may be retained adjacent to the front surface 200 of the planar bracket 120. In some embodiments, the rod 302 may move along the slot 208 to adjust a position of the mounting mechanism 140 relative to the planar bracket 120. In some embodiments, an end of the slot 208 may include a shape configured to cradle at least a portion of a cross-sectional shape of the rod 302. In this manner, the end of the slot 208 may be configured to independently retain the rod 302 to support the mounting mechanism 140.

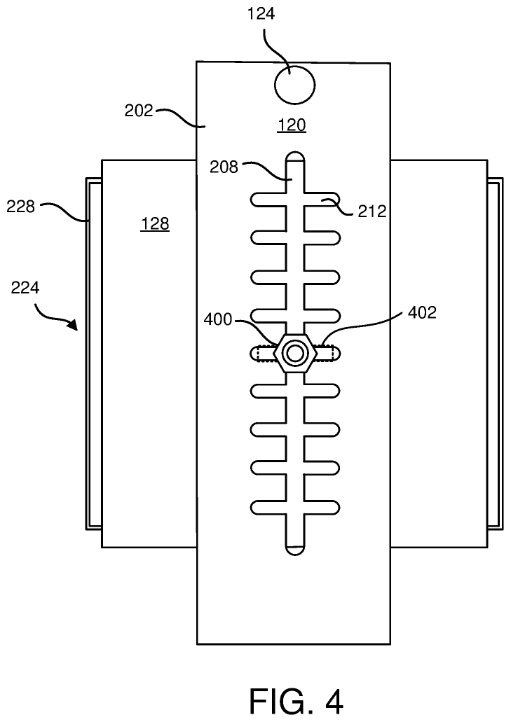

In some embodiments, one or more channels 212 may be integrated into the planar bracket 120 and may extend in a horizontal direction transverse to the longitudinal axis 118. In some embodiments, one or more of the channels 212 may intersect the slot 208, as discussed in more detail with reference to FIG. 4 below.

In some embodiments, the support element 128 may include a structure having a shape configured to surround at least a portion of the power distribution unit 130. For example, as shown, the support element 128 may include a hollow cube shape to support one end of an elongate power distribution unit 130. Of course, the support element 128 may include any suitable two-dimensional or three-dimensional shape. Some embodiments of the support element 128 may include an egress 230 integrated into a surface or portion of the support element 128 to accommodate the power cord 138 of the power distribution unit 130.

In some embodiments, the support element 128 may include at least one securing element 224 to retain the power distribution unit 130 relative to the support element 128. In some embodiments, the securing element 224 may include, for example, one or more openings 226, retaining bars 228, clips, protrusions, doors, or the like. In some embodiments, the opening 226 and/or retaining bar 228 may be configured to receive a strap (not shown) therethrough. In some embodiments, the strap (not shown) may be configured to engage the power distribution unit 130 within the support element 128 and/or obstruct an opening to the support element 128, thereby retaining the power distribution unit 130 within the support element 128 or securing the power distribution unit 130 with respect to the support element 128. In some embodiments, the strap (not shown) may be configured to extend around the power distribution unit 130 and attach to itself via hook and loop material, a rivet, a buckle, a snap, or any other suitable fastening mechanism. In other embodiments, a first end of the strap (not shown) may be attached to a first opening 226 or retaining bar 228 and a second end of the strap (not shown) may be configured to attached to a second opening 226 or retaining bar 228. In other embodiments, the opening 226, retaining bar 228, or other securing element 224 may be configured to engage a corresponding feature of the power distribution unit 130 and/or other feature coupled to the support element 128.

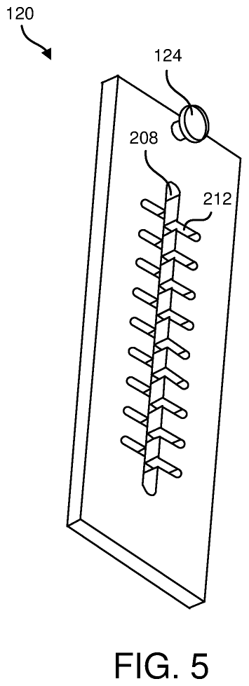

Referring now to FIGS. 4 and 5, in some embodiments, multiple horizontal channels 212 may intersect a single vertical slot 208. In some embodiments, one horizontal channel 212 may intersect one or more vertical slots 208. In some embodiments, the planar bracket 120 may include a vertical slot 208 and no horizontal channels 212. In some embodiments, each horizontal channel 212 may include a width similar or identical to the width of the vertical slot 208. In other embodiments, each channel 212 may include a width less than or greater than the width of the vertical slot 208. In some embodiments, each channel 212 may include dimensions identical to each other channel 212. In other embodiments, each channel 212 may have one or more dimensions different than one or more other channels 212.

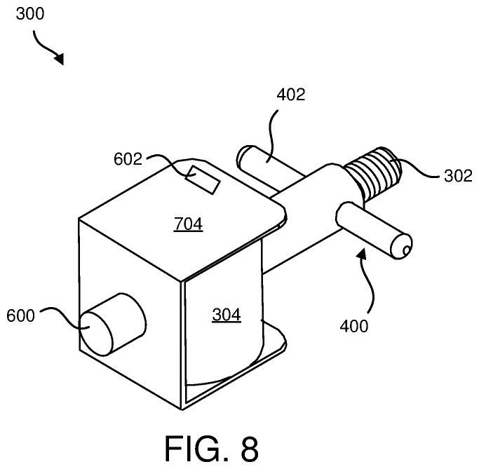

In some embodiments, the intersection between the channel 212 and the slot 208 may include at least one beveled edge. This feature may facilitate transitioning the rod 302 to move between the slot 208 and an intersecting channel 212. In other embodiments, the channel 212 may be configured to engage and/or retain a securing bar 402 coupled to the rod 302, as described in more detail with reference to FIG. 8 below.

In some embodiments, the securing bar 402 may include a width at least slightly greater than the channel 212. In this manner, the securing bar 402 may align with and fit against the channel 212 on the front surface 200 of the planar bracket 120, while the more narrow width of the channel 212 may prevent the securing bar 402 from sliding completely through. Similarly, in some embodiments, the channel 212 may include one or more obstructions to prevent the securing bar 402 from sliding through the channel 212. In other embodiments, the channel 212 may include one or more indentations into the front surface 200 of the planar bracket 120. In some embodiments, one or more protrusions may be coupled to the front surface 200 to form the channel 212.

In some embodiments, a fastener 400 may be configured to couple to an end of the rod 302 to secure the mounting mechanism 140 relative to the slot 208 and/or planar bracket 120. In some embodiments, the back surface 202 of the planar bracket 120 may include at least one indentation to maintain the fastener 400 in a desired position relative to the planar bracket 120. In these and other embodiments, the back surface 202 may be roughened, dimpled, or otherwise textured to provide friction to facilitate maintaining the position of the fastener 400 relative to the planar bracket 120. In some embodiments, the fastener 400 may include a washer (not shown) and/or nut configured to thread onto the rod 302. In some embodiments, the end of the rod 302 may project through the slot 208 and/or channel 212 such that it is accessible on the back surface 202 of the planar bracket 120. The fastener 400 may be threaded onto the rod 302 and tightened such that the washer and/or nut are retained adjacent to the back surface 202 of the planar bracket 120 and a position of the mounting mechanism 140 is secure. In other embodiments, the fastener 400 may include one or more screws, wing nuts, rivets, or any other suitable fastening device to secure the mounting mechanism 140 in a desired position relative to the planar bracket 120 via the slot 208 and/or channel 212.

In some embodiments, the securing bar 402 may be extend from an end of the rod 302. In these and other embodiments, the vertical slot 208 may include a width sufficient to allow the securing bar 402 to pass therethrough in a vertical direction prior to being rotated such that the securing bar 402 abuts the back surface 202 of the planar bracket 120. In some embodiments, the securing bar 402 may be rotated ninety degrees (90°) relative to the vertical slot 208. In some embodiments, the securing bar 402 may be rotated less than ninety degrees (90°) relative to the vertical slot 208. In these and other embodiments, an exposed end of the rod 302 may be threaded such that a nut (not shown) may be coupled to the rod 302 and tightened against the back surface 202 of the planar bracket 120 to secure a position of the rod 302 relative to the vertical slot 208.

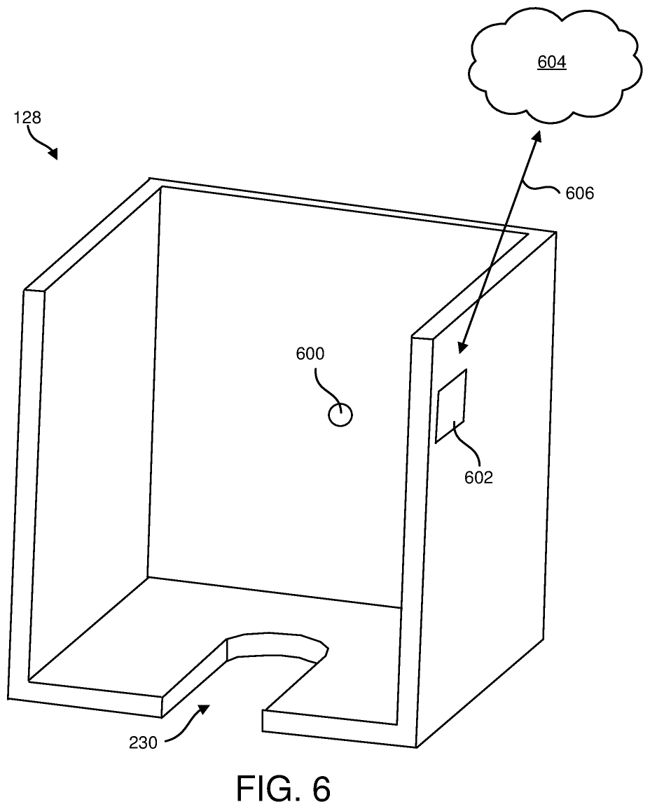

Referring now to FIG. 6 and as mentioned above, in some embodiments, the mounting mechanism 140 may include a hinge element 300 coupled to the support element 128. In some embodiments, the hinge element 300 may include a hinge element connection 600 coupling the hinge element 300 to the support element 128. In some embodiments, the hinge element connection 600 may include a protrusion or other feature adapted to engage a hole or opening in the support element 128. The hole or opening in the support element 128 may have a size and shape substantially matching or slightly greater than the cross-sectional size and shape of the hinge element connection 600 to facilitate a secure connection. In some embodiments, the hinge element connection 600 may be received into the hole or opening in the support element 128 via a press fit. In other embodiments, an adhesive or other mechanical element may be implemented to secure the connection between the hinge element connection 600 and the support element 128, such as a nut threaded onto a threaded shaft of the hinge element 300, a rivet inserted into a channel in the hinge element 300, a weld, or the like.

In some embodiments, the planar bracket 120 and/or the mounting mechanism 140 may include one or more sensors 602 configured to detect a position of the support element 128 relative to the planar bracket 120. In some embodiments, the position of the support element 128 relative to the planar bracket 120 may indicate a position of the power distribution unit 130 relative to the rack 104. In some embodiments, the sensors 602 may include, for example, a location sensor, a position sensor, an optical sensor, a motion sensor, and/or any other suitable sensor.

In some embodiments, the one or more sensors 602 may be configured to transmit a position signal 606 to a processor (not shown) via the cloud 604 or another wired or wireless network, for example. The position signal 606 may indicate a position of the support element 128 relative to the slot 208. In some embodiments, the position signal 606 may indicate a vertical position of the rod 302 relative to the slot 208. In these and other embodiments, the position signal 606 may further indicate a horizontal position of the rod 302 relative a channel 212. In some embodiments, the position signal 606 may identify the position as an intersection of a slot 208 with a channel 212.

In some embodiments, the sensor 602 may transmit the position signal 606 via a wireless connection such as a mobile telephone network. The wireless connection may also employ a Wi-Fi network based on any one of the Institute of Electrical and Electronics Engineers (“IEEE”) 802.11 standards. Alternatively, the wireless connection may be a BLUETOOTH® connection. In addition, the wireless connection may employ a Radio Frequency Identification (“RFID”) communication including RFID standards established by the International Organization for Standardization (“ISO”), the International Electrotechnical Commission (“IEC”), the American Society for Testing and Materials® (“ASTM”®), the DASH7™ Alliance, and EPCGlobal™.

Alternatively, the wireless connection may employ a ZigBee® connection based on the IEEE 802 standard. In one embodiment, the wireless connection employs a Z-Wave® connection as designed by Sigma Designs®. Alternatively, the wireless connection may employ an ANT® and/or ANT+® connection as defined by Dynastream® Innovations Inc. of Cochrane, Canada. In some embodiments, the wireless connection may employ 5G, LTE-M, NB-IoT, LoRaWAN, SigFox, or any other suitable IEEE 802 standard or protocol.

In some embodiments, the wireless connection may be an infrared connection including connections conforming at least to the Infrared Physical Layer Specification (“IrPHY”) as defined by the Infrared Data Association® (“IrDA”®). Alternatively, the wireless connection may be a cellular telephone network communication. All standards and/or connection types include the latest version and revision of the standard and/or connection type as of the filing date of this application.

In some embodiments, the processor may be configured to recommend one or more service actions steps to a user based on the position and/or orientation of the power distribution unit 130. For example, in some embodiments, the processor may be configured to recommend moving one or more cords or repositioning the power distribution unit 130 prior to servicing a target component of an electronic device 102 in the rack 104. In some embodiments, the recommended service action steps may be transmitted from the processor to a user device such as a mobile phone, a handheld device, a desktop computer, a laptop computer, or any other suitable device.

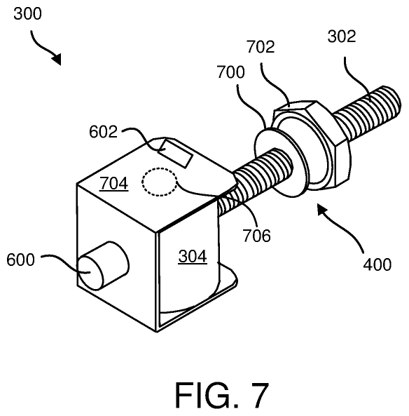

Referring now to FIGS. 7 and 8, in some embodiments, one or more sensors 602 may transmit the position signal 606 to indicate an orientation of the support element 128 relative to the planar bracket 120. For example, in some embodiments, the hinge element 300 may include a hinge 304 configured to rotate the support element 128 relative to the planar bracket 120. In some embodiments, the support element 128 may rotate between zero degrees (0°) and one hundred eighty degrees (180°) relative to the planar bracket 120. In other embodiments, the support element 128 may rotate between zero degrees (0°) and two hundred seventy degrees (270°) or more relative to the planar bracket 120.

In some embodiments, the hinge 304 may be mounted in at least a portion of a housing 704. In some embodiments, the hinge element 300 may include a hinge point 706 connecting the hinge 304 to the housing 704. In some embodiments, the hinge point may include a recess on the top and/or bottom of the housing 704 and a post, clip, or other mechanical element or device received by the recess to connect the hinge 304 to the housing 704. Similarly, in some embodiments, the housing 704 may be molded or otherwise formed to include the hinge element connection 600 to connect the hinge element 300 to the support element 128. In some embodiments, the hinge element connection 600 may be welded or otherwise coupled to the housing 704.

In some embodiments, the rod 302 may be configured to extend in a transverse direction from the hinge 304. The rod 302 may include a length sufficient to extend through the planar bracket 120 and to receive the fastener 400. In some embodiments, at least a portion of the rod 302 may be threaded. In some embodiments, as shown in FIG. 7, the fastener 400 may include a washer 700 and/or an adjustable nut 702. In these and other embodiments, the nut 702 or another suitable fastener 400 may include threads configured to mate with the threads of the rod 302. In other embodiments, the fastener 400 may be configured to couple to at least a portion of the rod 302 via any suitable mechanical connection. In some embodiments, a first nut 702 may be coupled to the rod 302 and disposed on the front surface 200 of the planar bracket 120 and a second nut 702 may be coupled to the rod 302 and disposed on the back surface 202. In this manner, the planar bracket 120 may be secured between the two. Other embodiments may include one or more lock washers and/or nuts 702 and flat washers 700 to secure the planar bracket 120 therebetween. In some embodiments, as shown in FIG. 8, the fastener 400 may include a securing bar 402 extending in a transverse direction from the rod 302. In some embodiments, the securing bar 402 may include dimensions substantially corresponding to at least one channel 212 of the planar bracket 120. In these and other embodiments, the securing bar 402 may engage the channel 212 such that the securing bar 402 is retained on the front surface 200 of the planar bracket 120 when the rod 302 extends through the slot 208. In some embodiments, the fastener 400 may be coupled to the portion of the rod 302 extending through the slot 208. In this manner, the securing bar 402 may prevent movement of the mounting mechanism 140 in a vertical direction (parallel to the longitudinal axis 118) while the fastener 400 may prevent movement of the mounting mechanism 140 in a horizontal direction (transverse to the longitudinal axis 118).

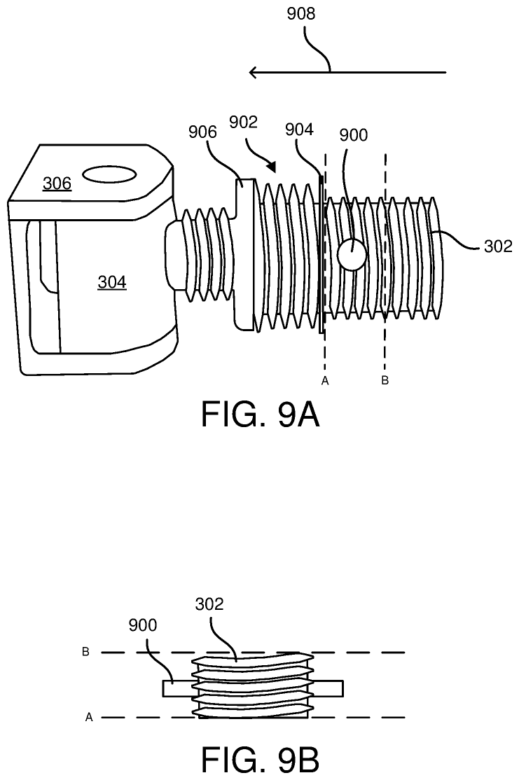

Referring now to FIGS. 9A and 9B, in some embodiments, the fastener 400 may include a locking pin 900 integrated with or coupled to at least a portion of the rod 302. In some embodiments, the locking pin 900 may include a size and shape configured to engage one or more corresponding apertures within the slot 208 of the planar bracket 120. In other embodiments, the locking pin 900 may include a size and shape configured to engage a channel 212 of the planar bracket 120. In some embodiments, the locking pin 900 may extend in a transverse direction relative to the rod 302. In some embodiments, the locking pin 900 may extend through the rod 302 in opposite transverse directions. In other embodiments, the locking pin 900 may extend from the rod 302 in a single transverse direction.

In some embodiments, the locking pin 900 may be selectively actuated to extend from the locking pin 900. For example, in one embodiment, the locking pin 900 may be biased within the rod 302 until automatically or manually actuated. As shown in FIG. 9A, in some embodiments, the locking pin 900 may be selectively obstructed by a compression spring 902 surrounding at least a portion of the rod 302. As the rod 302 is pushed through the slot 208, the compression spring 902 may be compressed in a transverse direction 908. As the compression spring 902 compresses towards the hinge 304, the portion of the rod 302 containing the locking pin 900 may be exposed and unobstructed such that the locking pin 900 automatically springs out from the rod 302. In other embodiments, when the rod 302 is pushed through the slot 208, an opening for the locking pin 900 is exposed and the locking pin 900 is inserted into the opening. In other embodiments, the locking pin 302 is initially positioned in line with the slot 208 and when the rod 302 is pushed into the slot 208, the locking pin 900 extends past through the slot 208 enough for the locking pin 900 to be rotated to engage the back surface 202 of the planar bracket 120, for example at a horizontal channel 212.

In some embodiments, the locking pin 900 may engage one or more corresponding apertures in the slot 208 to secure a position of the mounting mechanism 140 relative to the planar bracket 120. In other embodiments, the locking pin 900 may engage a channel 212 of the planar bracket 120 to lock the mounting mechanism 140 in place relative to the planar bracket 120. In some embodiments, a spring retention washer 904 may be moved along the rod 302 to selectively secure the compression spring 902 in a compressed position.

Embodiments may be practiced in other specific forms. The described embodiments are to be considered in all respects only as illustrative and not restrictive. The scope of the invention is, therefore, indicated by the appended claims rather than by the foregoing description. All changes which come within the meaning and range of equivalency of the claims are to be embraced within their scope.

What is claimed is:

1. An apparatus comprising:
a planar bracket extending along a longitudinal axis, wherein the planar bracket is configured to couple to a rack configured to house at least one electronic device, and wherein the planar bracket comprises at least one slot extending parallel to the longitudinal axis;
a mounting mechanism configured to engage the planar bracket, the mounting mechanism comprising:
a hinge element comprising a rod configured to engage the slot; and
a support element coupled to the hinge element and configured to support a power distribution unit, the support element configured to rotate relative to the rod.

2. The apparatus of claim 1, wherein the planar bracket further comprises at least one channel extending in a direction transverse to the longitudinal axis, wherein the at least one channel intersects the at least one slot.

3. The apparatus of claim 2, wherein the rod further comprises a securing bar extending in a transverse direction relative thereto, wherein the securing bar is configured to selectively engage the at least one channel.

4. The apparatus of claim 1, wherein the rod is movable along the slot to adjust a position of the mounting mechanism with respect to the planar bracket.

5. The apparatus of claim 1, wherein the support element is configured to support the power distribution unit such that the power distribution unit is disposed parallel to the longitudinal axis.

6. The apparatus of claim 1, wherein the support element is configured to couple to an end of the power distribution unit.

7. The apparatus of claim 1, wherein the support element comprises at least one securing element configured to couple at least a portion of the power distribution unit to the support element.

8. The apparatus of claim 7, wherein the at least one securing element comprises at least one of an aperture and a retaining bar configured to receive a strap therethrough.

9. The apparatus of claim 1, further comprising the power distribution unit, wherein the rack comprises at least one aperture and wherein the planar bracket comprises an attachment element configured to engage the at least one aperture such that the planar bracket is coupled to the rack.

10. The apparatus of claim 1, further comprising at least one fastener configured to fix a position of the mounting mechanism relative to the slot.

11. The apparatus of claim 1, further comprising at least one sensor coupled to at least one of the planar bracket and the mounting mechanism, wherein the at least one sensor is configured to detect a position of the support element relative to the planar bracket and to transmit a position signal to a processor, wherein the position signal indicates the position.

12. A system comprising:
a rack configured to retain at least one electronic device, wherein the at least one electronic device is configured to couple to a power distribution unit having at least one port;
a planar bracket coupled to the rack and extending along a longitudinal axis, the planar bracket comprising at least one slot extending therethrough;
a hinge element comprising a rod configured to engage the slot such that the rod is transverse to the longitudinal axis and is movable along the slot; and
a support element coupled to the hinge element and configured to support the power distribution unit adjacent to the rack, wherein the support element is configured to rotate about an axis, wherein the axis is parallel to the longitudinal axis.

13. The system of claim 12, further comprising at least one sensor coupled to at least one of the planar bracket, the hinge element, the support element, and the rack, wherein the at least one sensor is configured to detect a position of the support element relative to the planar bracket.

14. The system of claim 13, wherein the at least one sensor comprises at least one of a location sensor, a position sensor, an optical sensor, and a motion sensor.

15. The system of claim 14, further comprising a processor in communication with the at least one sensor, wherein the processor is configured to determine an orientation of the power distribution unit based on the position.

16. The system of claim 15, wherein the processor is further configured to recommend at least one service action step to a user based on the orientation.

17. The system of claim 12, wherein the planar bracket further comprises at least one channel intersecting the at least one slot in a direction transverse to the longitudinal axis.

18. The system of claim 17, wherein the rod comprises a post extending in a transverse direction relative thereto, wherein the post is configured to selectively engage the at least one channel.

19. The system of claim 12, wherein the support element is configured to support the power distribution unit such that the power distribution unit is disposed parallel to the longitudinal axis.

20. An apparatus comprising:
a planar bracket extending along a longitudinal axis, wherein the planar bracket is configured to couple to a rack configured to house at least one electronic device, and wherein the planar bracket comprises at least one slot extending parallel to the longitudinal axis and at least one channel extending in a direction transverse to the longitudinal axis and intersecting the slot;
a mounting mechanism configured to engage the planar bracket, the mounting mechanism comprising:
a hinge element comprising a rod configured to engage the slot such that the rod is movable along the slot and a post extending in a transverse direction relative to the rod, wherein the post is configured to selectively engage the at least one channel;
a fastener configured to fix a position of the rod relative to the slot;
a support element coupled to the hinge element and configured to support a power distribution unit such that the power distribution unit is disposed parallel to the longitudinal axis, wherein the support element is configured to rotate relative to the rod; and
a securing element configured to couple at least a portion of the power distribution unit to the support element; and
at least one sensor coupled to at least one of the planar bracket and the mounting mechanism, wherein the at least one sensor is configured to detect a position of the support element relative to the planar bracket and to transmit a position signal to a processor, wherein the position signal indicates the position.
